(19) United States
(12) Patent Application Publication
(10) Pub. No.: US 2009/0224797 A1
(43) Pub. Date: Sep. 10, 2009

(54) ELECTRONIC DEVICE

(76) Inventor: Satoshi Tanaka, Chiba (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/397,653

(22) Filed: Mar. 4, 2009

(30) Foreign Application Priority Data
Mar. 6, 2008 (JP) 2008-057013

(51) Int. Cl. H03K 17/16

(52) U.S. Cl. 326/30

(57) ABSTRACT

An electronic device having a circuit configuration in which a terminating resistor is connected to a data signal line is disclosed, including: a data processing part; one or more data storing parts being main storage units of the data processing part; a termination voltage generating part to apply a termination voltage to the data signal line connecting the data processing part to the one or more data storing parts through the terminating resistor; and a current supply intercepting part connected between the data signal line and the terminating resistor. The data processing part detects a configuration of the one or more data storing parts, and enables the terminating resistor to supply current by the current supply intercepting part between the data signal line and the terminating resistor, or disables the terminating resistor to intercept the current between the data signal line and the terminating resistor, based on a detection result.

### BACKGROUND OF THE INVENTION

1. Field of the Invention

The present invention is related to an electronic device, and more particularly to the electronic device including a circuit configuration in which a terminating resistor is connected to a data signal line.

2. Description of the Related Art

For example, a circuit signal line such as a DDR SDRAM (Double Data Rate SDRAM) employing an SSTL (Stub Series Termination Logic)-2 standard suppresses a signal reflection and an amplitude between DRAM devices at a memory access by configuring a resistor (terminating resistor) pulled up at the termination voltage.

In particular, in an electronic device including a plurality of DIMM (Dual Inline Memory Module) sockets, configurations vary for DIMMs connected to the DIMM sockets. The DIMM is a memory board (memory module) designed for an expansion memory. In the memory board (memory module), a plurality of DRAM devices are mounted and wired on a substrate, and connection terminals are provided to connect to the DIMM sockets. That is, the number of the DRAM devices existing on the data signal line is not uniquely determined.

For example, in Japanese Laid-open Patent Application No. 10-198473, the terminating resistor absorbs an affect due to a difference of the number of the DRAM devices existing on the data signal line, so that there is a great effect on uniformly satisfying a waveform quality in any configuration of the DIMM.

However, it is known that in a state in that there is no memory access, power consumption of the electronic device becomes greater due to a current from the terminating resistor. It should be noted that the Japanese Laid-open Patent Application No. 10-198473 discloses to vary a value of the terminating resistor to reduce distortion of the waveform. However, the Japanese Laid-open Patent Application No. 10-198473 does not disclose how to reduce the power consumption due to the current flowing through the terminating resistor.

### SUMMARY OF THE INVENTION

The present invention solves or reduces one or more of the above problems.

In an aspect of this disclosure, there is provided an electronic device having a circuit configuration in which a terminating resistor is connected to a data signal line, the electronic device including: a data processing part; one or more data storing parts configured to be main storage units of the data processing part; a termination voltage generating part configured to apply a termination voltage to the data signal line connecting the data processing part to the one or more data storing parts through the terminating resistor; and a current supply intercepting part configured to be connected between the data signal line and the terminating resistor, wherein the data processing part detects a configuration of the one or more data storing parts, and enables the terminating resistor to supply current by the current supply intercepting part between the data signal line and the terminating resistor, or disables the terminating resistor to intercept the current between the data signal line and the terminating resistor, based on a detection result.

In other aspect of the present invention, component elements, expressions, or any combination thereof according to the present invention can be applied in a method, an apparatus, a system, a computer program, a recording medium, a data structure, and a like.

### BRIEF DESCRIPTION OF THE DRAWINGS

In the following, embodiments of the present invention will be described with reference to the accompanying drawings.

FIG. 1 is a block diagram illustrating a circuit configuration of an electronic device according to a first embodiment;

FIG. 2 is the flowchart for explaining an example of steps conducted by the electronic device according to the first embodiment;

FIG. 3 is a block diagram illustrating a circuit configuration of an electronic device according to a second embodiment;

FIG. 4 is the flowchart for explaining an example of steps conducted by the electronic device according to the second embodiment;

FIG. 5 is a block diagram illustrating a circuit configuration of an electronic device according to a third embodiment;

FIG. 6A and FIG. 6B are block diagrams illustrating a circuit configuration of an electronic device according to a fourth embodiment;

FIG. 7 is a block diagram illustrating a circuit configuration of an electronic device according to a fifth embodiment;

FIG. 8 is a block diagram illustrating a circuit configuration of an electronic device according to a sixth embodiment; and

FIG. 9 is the flowchart for explaining an example of steps conducted by the electronic device according to the sixth embodiment.

### DESCRIPTION OF THE PREFERRED EMBODIMENTS

In the following, embodiments of the present invention to will be described with reference to the accompanying drawings. In the following embodiments, an electronic device may be an information processing apparatus such as a laser printer, a copier, a facsimile, or a like.

In the embodiments, in a DDR-SDRAM employing a SSTL-2 standard, a configuration of a DIMM does not vary, or excessive power consumption is reduced by disabling a terminating resistor in a case in which a signal quality satisfies a device standard even if the terminating resistor is not mounted. In the embodiments, by automatically determining whether the terminating resistor is required or is not required for each configuration of the DIMM, it is possible to realize both ensuring waveform quality and reducing power consumption, even if there are a plurality of configurations of DIMMs.

### First Embodiment

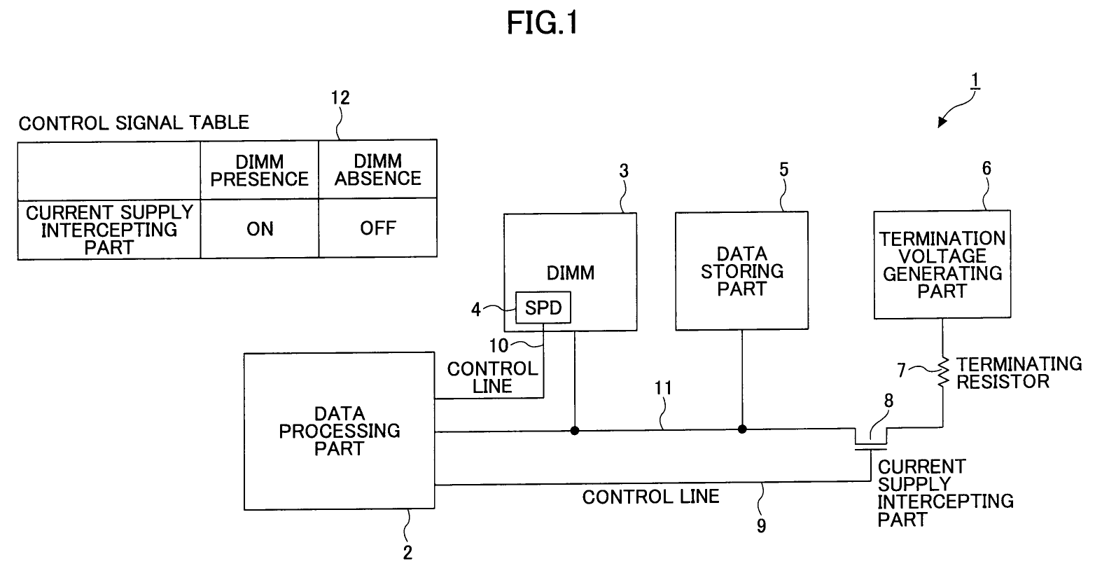

FIG. 1 is a block diagram illustrating a circuit configuration of an electronic device according to a first embodiment. In the first embodiment, an electronic device 1 includes a data processing part 2, a DIMM 3 mounting an SPD (Serial Presence Detect) 4, a data storing part 5, a termination voltage generating part 6, a terminating resistor 7, a current supply intercepting part 8, a control line 9, a control line 10, and a data signal line 11.

The data processing part 2 is connected to the DIMM 3 and the data storing part 5 through the data signal line 11. The DIMM 3 is connected to the data signal line 11 through a DIMM socket. The DIMM 3 is detachably connected. For example, the SPD 4 mounted in the DIMM 3 is an electrically writable and programmable ROM (EEPROM (Electrically Erasable and Programmable Read Only Memory)). The SPD 4 records a specification of a memory including a capacity of the DIMM 3, an access speed, an access method, and a like. The data processing part 2 is connected through the SPD 4 and the control line 10, and the specification of the memory can be read out from the SPD 4.

The data storing part 5 is directly mounted on the substrate and is connected to the data signal line 11. The termination voltage generating part 6 is connected to the data signal line 11 through the terminating resistor 7 and the current supply intercepting part 8, and applies a termination voltage to the data signal line 11 through the terminating resistor 7. The current supply intercepting part 8 is connected to the data processing part 2 through the control line 9, and supplies or intercepts a current between the terminating resistor 7 and the data signal line 11 by a control of the data processing part 2.

The data processing part 2 determines a presence or absence of the DIMM 3 by whether or not the specification of the memory from the SPD 4 can be read. The data processing part 2 controls the current supply intercepting part 8 to turn on (current supply) to enable the terminating resistor 7 when the DIMM 3 is present, based on a control signal table 12. The data processing part 2 controls the current supply intercepting part 8 to turn off (current intercept) to disable the terminating resistor 7 when the DIMM 3 is absence, based on the control signal table 12.

The control signal table 12 illustrates an example in which a device load capacity with respect to the data signal line 11 is small and a waveform quality is satisfied without an terminal by the terminating resistor 7, when the DIMM 3 is not connected, and the device load capacity with respect to the data signal line 11 is large and the waveform quality is not satisfied without the terminal by the terminating resistor 7, when the DIMM 3 is connected.

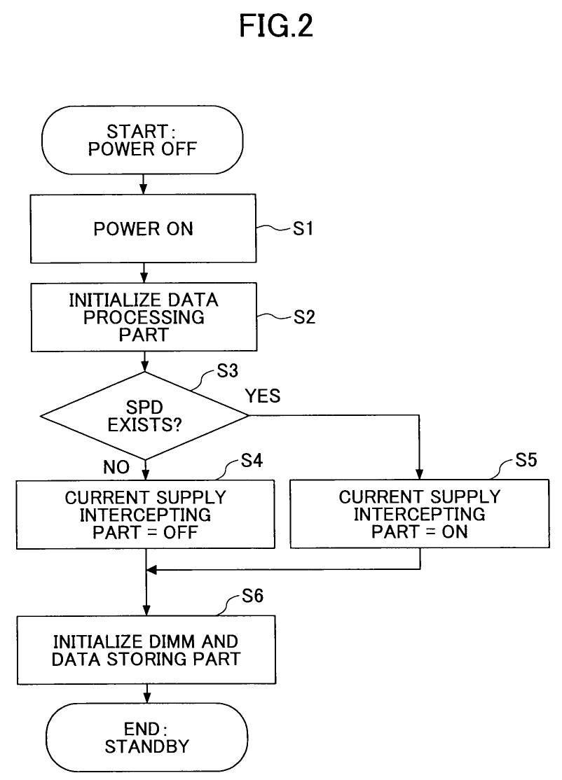

The data processing part 2 controls the current supply and the current intercept between the terminating resistor 7 and the data signal line 11, in accordance with steps of a flowchart illustrated in FIG. 2. FIG. 2 is the flowchart for explaining an example of steps conducted by the electronic device according to the first embodiment.

In step S1, the electronic device 1 is turned on from a power off state. In step S2, the data processing part 2 is initialized. In step S3, the data processing part 2 determines whether the SPD 4 is present or absent, by whether or not the specification of the memory from the SPD 4 can be read.

When the data processing part 2 determines that the SPD 4 is absence, the data processing part 2 advances to step S4. In the step 4, the data processing part 2 recognizes that the DIMM 3 is not connected and turns off (interception) the current supply intercepting part B. When the data processing part 2 determines that the SPD 4 is present, the data processing part 2 advances to step S5. In the step 5, the data processing part 2 recognizes that the DIMM 3 is connected and turns on (current supply) the current supply intercepting part 8. In step S6 following to the step S4 or the step S5, after the data processing part 2 initializes the DIMM 4 and the data storing part 5, the entire electronic device 1 is activated and is in a stand-by state.

In the circuit configuration in FIG. 1, the current supply intercepting part 8 is provided between the terminating resistor 7 and the data signal line 11, on/off of the current supply intercepting part 8 is controlled based on the presence or the absence of the DIMM 3 (the configuration of the DIMM 3) detected by the data processing part 2. The current supply intercepting part 8 is turned off in a configuration of the DIMM 3 (absence of the DIMM 3) in which the terminating resistor 7 is unnecessary, and the terminating resistor 7 is disabled. Accordingly, it is possible to reduce power consumption.

Also, the current supply intercepting part 8 is turned on in a configuration of the DIMM 3 (presence of the DIMM 3) in FIG. 1 in which the terminating resistor 7 is necessary, and the terminating resistor 7 is enabled. Accordingly, it is possible to ensure the waveform quality.

### Second Embodiment

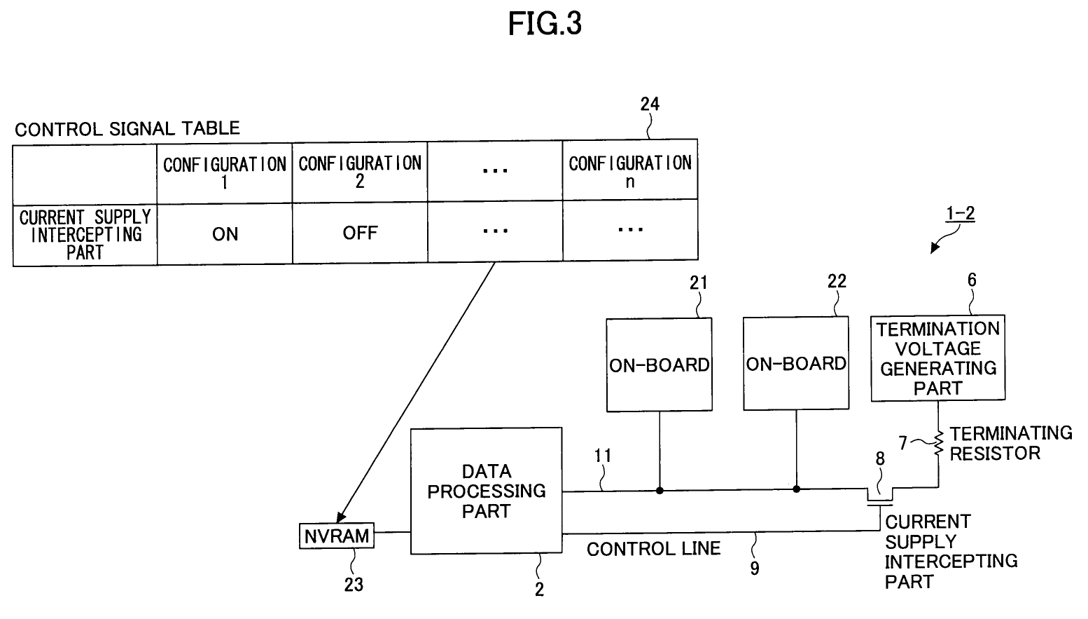

FIG. 3 is a block diagram illustrating a circuit configuration of an electronic device according to a second embodiment. In the second embodiment, an electronic device 1-2 includes the data processing part 2, the termination voltage generating part 6, the terminating resistor 7, the current supply intercepting part 8, the control line 9, the data signal line 11, data storing parts 21 and 22 which are on-board and are directly mounted on the substrate, and an NVRAM (Non-Volatile RAM) 23. In the block diagram of FIG. 3, parts that are the same as those illustrated in FIG. 1 are given the same reference numbers, and explanation thereof will be omitted.

The data processing part 2 is connected to the data storing parts 21 and 22 which are on-board through the data signal line 11. The data storing parts 21 and 22 which are on-board do not include the SPD 4 described in the first embodiment.

Thus, the data processing part 2 can not determine the presence or absence of the data storing parts 21 and 22 which are on-board by whether or not reading the specification of the memory from the SPD 4 as described in the first embodiment. Consequently, in the electronic device 1-2 in the second embodiment, it is determined whether the presence or the absence of the data storing parts 21 and 22 which are on-board by a presence or an absence of an on-board memory setting stored in the NVRAM 23. The data processing part 2 automatically determines whether the terminating resistor 7 is necessary or unnecessary, by using a control signal table 24 for each configuration of the data storing parts 21 and 22 which are on-board and connected to the data signal line 11, so as to control on and off (current supply and interception) of the current supply intercepting part 8.

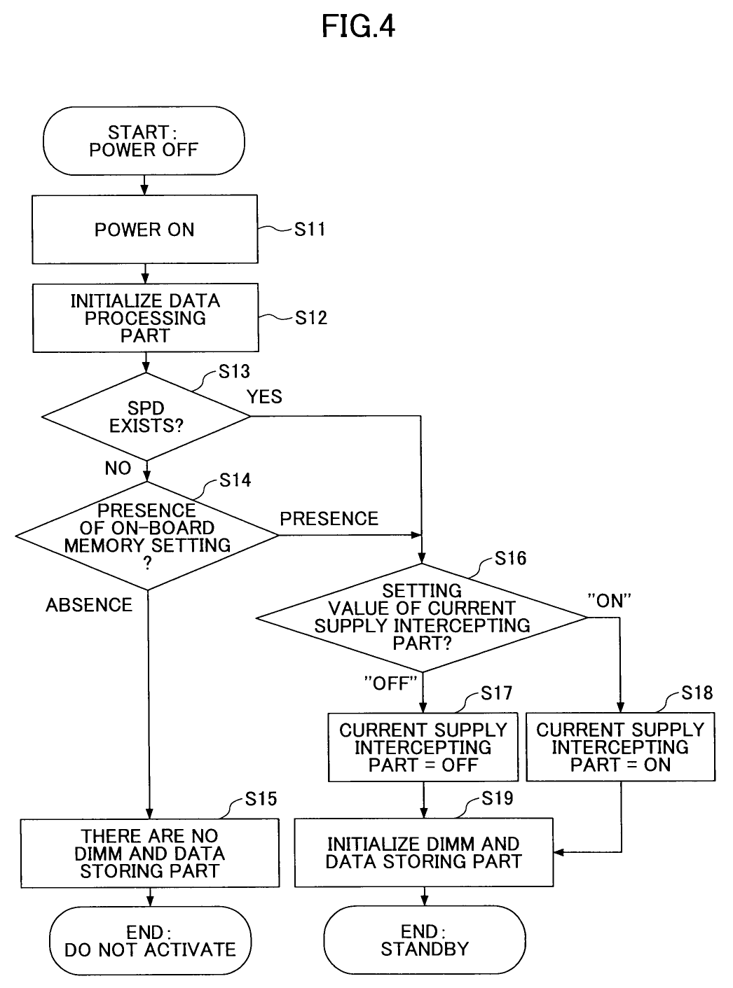

The data processing part 2 supplies or intercepts current between the terminating resistor 7 and the data signal line 11 in accordance with steps of a flowchart illustrated in FIG. 4. FIG. 4 is the flowchart for explaining an example of steps conducted by the electronic device according to the second embodiment.

In step S11, the electronic device 1-2 is turned on from the power off state. In step S12, the data processing part 2 is initialized. In step S13, the data processing part 2 determines whether the SPD 4 is present or absent by whether or not reading the specification of the memory from the SPD 4. When it is determined that the SPD 4 is absence, the data processing part 2 advances to step S14, and determines whether the data storing parts 21 and 22 which are on-board are present or absent, by the presence or the absence of the on-board memory setting stored in the NVRAM 23.

When it is determined that the on-board setting is absence in the NVRAM 23 and the data storing parts 21 and 22 of the on-board are absence, the data processing part advances to step S15. In the step S15, the data processing part recognizes that the DIMM 3 and the data storing parts 21 and 22 of the on-board are connected to the data signal line 11, and stops activating the electronic device 1-2.

On the other hand, when it is determined that the SPD 4 is present in the step S13, or when the on-board memory setting is present in the NVRAM 23 in the step S14 and it is determined that the data storing parts 21 and 22 of the on-board are presence, the data processing part 2 determines “ON” (current supply) or “OFF” (interception) of the current supply intercepting part 8 by referring to the control signal table 24, based on a configuration of the DIMM 3 or the data storing parts 21 and 22 connected to the data signal line 11.

When it is determined that “OFF” (interception) is set in the control signal table 24, the data processing part 2 advances to step S17 and turns off the current supply intercepting part 8 (interception). On the other hand, when it is determined that “ON” (current supply) is set, the data processing part 2 advances to step S18 and turns on the current supply intercepting part 8 (current supply).

Subsequently, the data processing part 2 advances to step S19 following the step S17 or the step S18. After the data processing part 2 initializes the DIMM 3 or the data processing parts 21 and 22 of the on-board, the entire electronic device 1-2 is activated and is in the stand-by state.

In the circuit configuration in FIG. 3, since the control signal table 24 is stored in the NVRAM 23, the data processing part 2 determines on or off of the current supply intercepting part 8 based on the presence or the absence of the data storing parts 21 and 22 of the on-board detected by the data processing part 2. Moreover, in the circuit configuration in FIG. 3, by storing the control signal table 24 in the NVRAM 23, it is possible to set “ON” or “OFF” of the current supply intercepting part 8 by corresponding to configurations of the data storing parts 21 and 22 as various on-board chips.

In the circuit configuration in FIG. 3, by turning off the current supply intercepting part 8 and disabling the terminating resistor 7 in a configuration in which the terminating resistor 7 is unnecessary, it is possible to reduce the power consumption. Moreover, in the circuit configuration in FIG. 3, by turning on the current supply intercepting part 8 and enabling the terminating resistor 7 in a configuration in which the terminating resistor 7 is necessary, it can be realized to ensure the waveform quality.

For example, in the circuit configuration in FIG. 3, in a case in which a different memory capacities are mounted for a plurality of device types using the same substrate (PWB (Printed Wiring Board)), it is possible to ensure the waveform quality and reduce the power consumption even if the same substrate is used.

### Third Embodiment

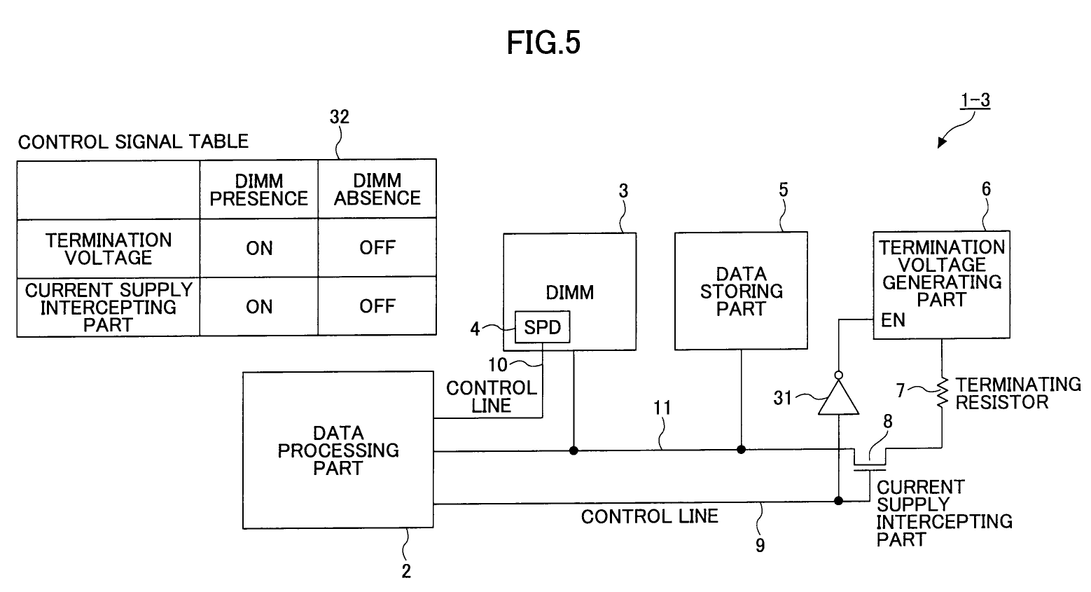

FIG. 5 is a block diagram illustrating a circuit configuration of an electronic device according to a third embodiment. In an electronic device 1-3 according to the third embodiment, a configuration of connecting the control line 9 and a control terminal (EN) of the termination voltage generation part 6 via an inverter 31 is provided with in addition to the configuration of the electronic device 1 in FIG. 1. In the electronic device 1-3 according to the third embodiment, an on/off logic of the current supply intercepting part 8 is inversed to an on/off logic of the termination voltage generating part 6.

The data processing part 2 turns on the current supply intercepting part 8 (current supply) based on a control signal table 32 when the DIMM 3 is present, and also controls the terminating resistor 7 to be enabled by turning off (applying a terminal voltage to) the control terminal (EN) of the termination voltage generating part 6. The data processing part 2 turns off the current supply intercepting part 8 based on the control signal table 32 when the DIMM 3 is absence, and also controls the terminating resistor 7 to be disabled by turning on (stopping applying the terminal voltage to) the control terminal (EN) of the termination voltage generating part 6.

In the circuit configuration in FIG. 5, by turning on the control terminal (EN) of the termination voltage generating part 6 simultaneously when turning off the current supply intercepting part 8, it can be realized to reduce the power consumption. Also, in the circuit configuration in FIG. 5, since the terminating resistor 7 is enabled by turning off the control terminal (EN) of the termination voltage generating part 6 simultaneously when turning on the current supply intercepting part 8, it can be realized to ensure the waveform quality.

### Fourth Embodiment

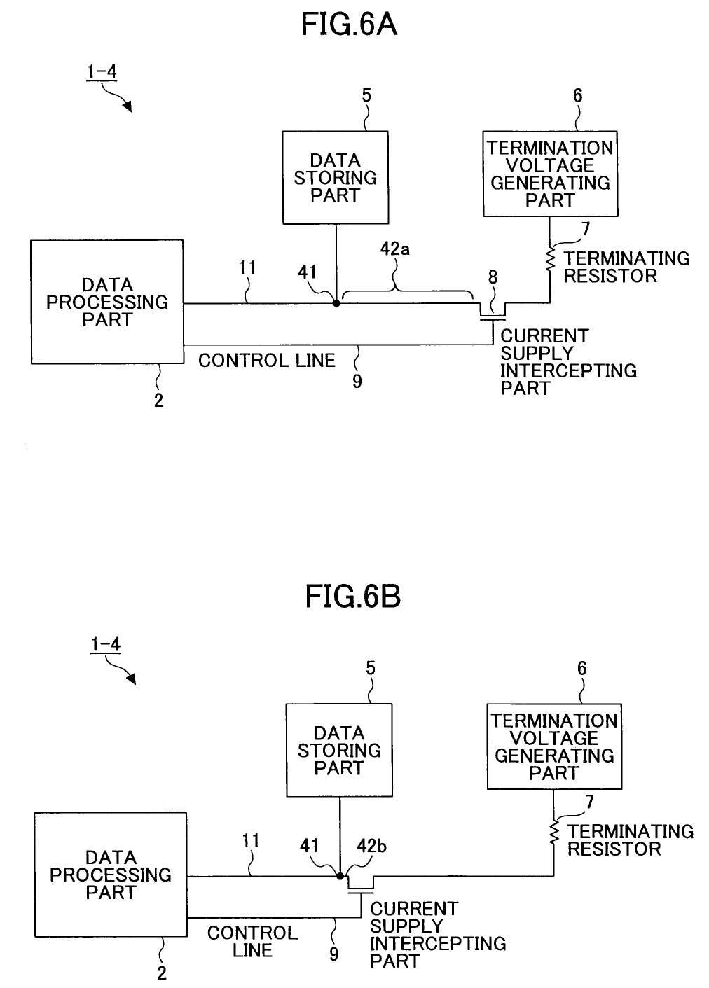

FIG. 6A and FIG. 6B are block diagrams illustrating a circuit configuration of an electronic device according to a fourth embodiment. In an electronic device 1-4 according to the fourth embodiment as illustrated in FIG. 6A, in a case in which a wiring length 42a between a branch point 41 branching to a direction of the termination voltage generating part 6 from the data signal line 11 and the current supply intercepting part 8 is longer, when the current supply intercepting part 8 turns off (interception), there is a possibility that an adverse affect is given to the waveform quality of the data signal line 11 due to an influence of a signal reflection caused by a wiring pattern.

Therefore, as illustrated in FIG. 6B, in the electronic device 1-4 according to the fourth embodiment, a wiring length 42b between the branch point 41 branching to a direction of the termination voltage generating part 6 from the data signal line 11 and the current supply intercepting part 8 is made to be shorter as much as possible. Accordingly, when the current supply intercepting part 8 is turned off (interception), it is possible to reduce the influence of the signal reflection caused by the wiring pattern, and then, it can be realized to ensure the waveform of the data signal line 11.

### Fifth Embodiment

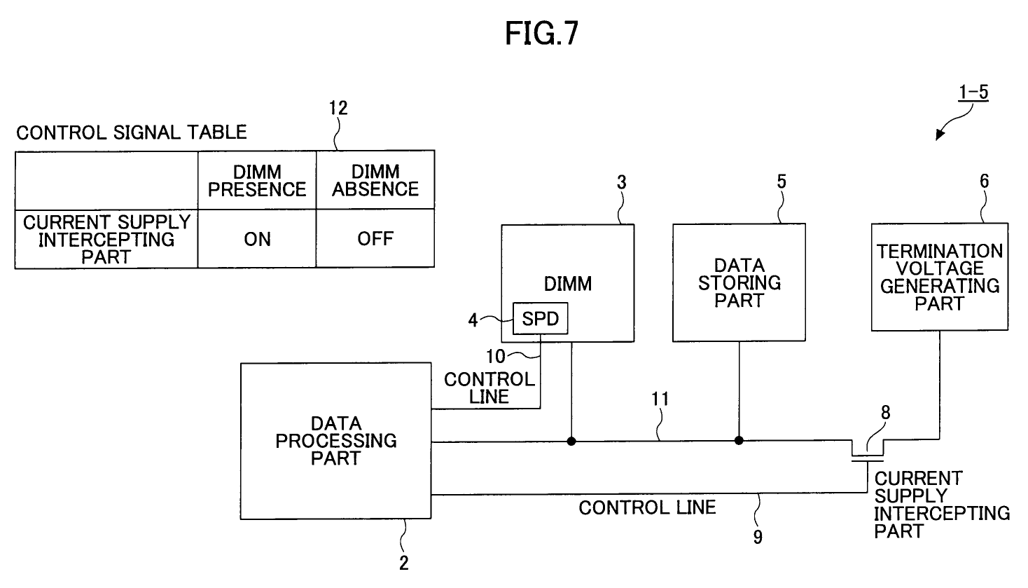

FIG. 7 is a block diagram illustrating a circuit configuration of an electronic device according to a fifth embodiment. In an electronic device 1-5 according to the fifth embodiment, in a case of using a semiconductor switch as the current supply intercepting part 8, the inventor focuses on that a resistance component (on-resistance) exists as a characteristic of a device when the current is supplied, recognizes the on-resistance as a terminating resistor, and then, omits the terminating resistor 7.

In the electronic device 1-5 according to the fifth embodiment, the on-resistance of the current supply intercepting part 8 is selected or adjusted so as to function as the terminating resistor 7, and the terminating resistor 7 becomes unnecessary. Accordingly, in the electronic device 1-5 according to the fifth embodiment, it is not required to mount the terminating resistor 7 on the substrate, and it is possible to reduce cost by reducing a layout area on the substrate and the number of components.

### Sixth Embodiment

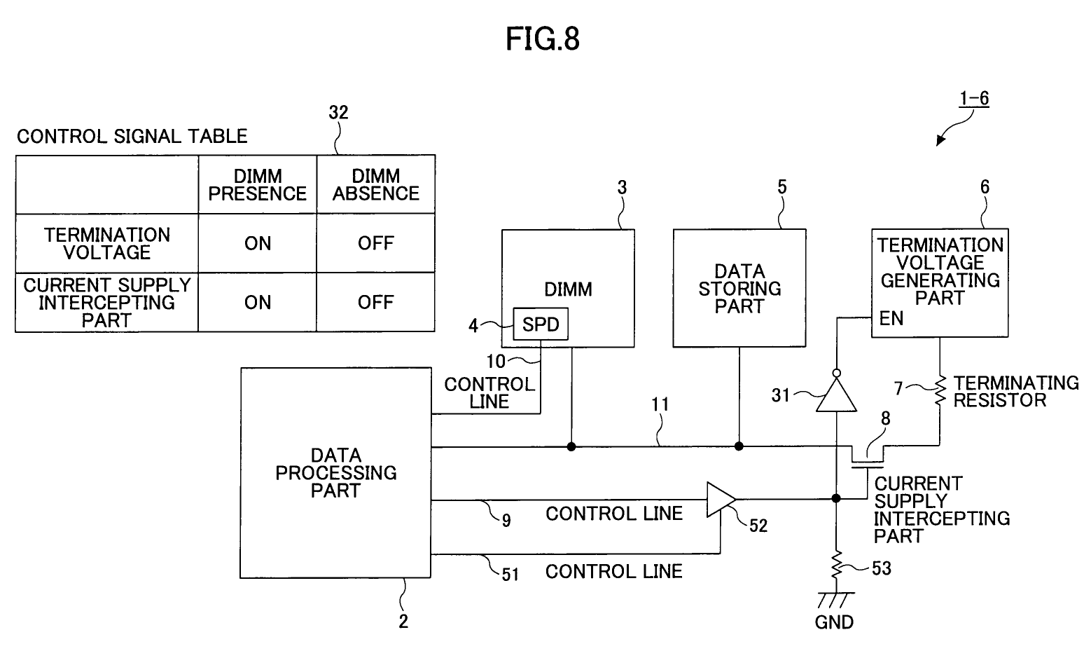

FIG. 8 is a block diagram illustrating a circuit configuration of an electronic device according to a sixth embodiment. In an electronic device 1-6 according to the sixth embodiment, a control line 51, a control part 52, and a resistor 53 are provided in addition to the circuit configuration of the electronic device 1-5. The control part 52 is provided on the control line 9. The control part 52 is connected to the data processing part 2 through the control line 51, and supplies or intercepts the current to the control line 9 in response to a control of the data processing part 2.

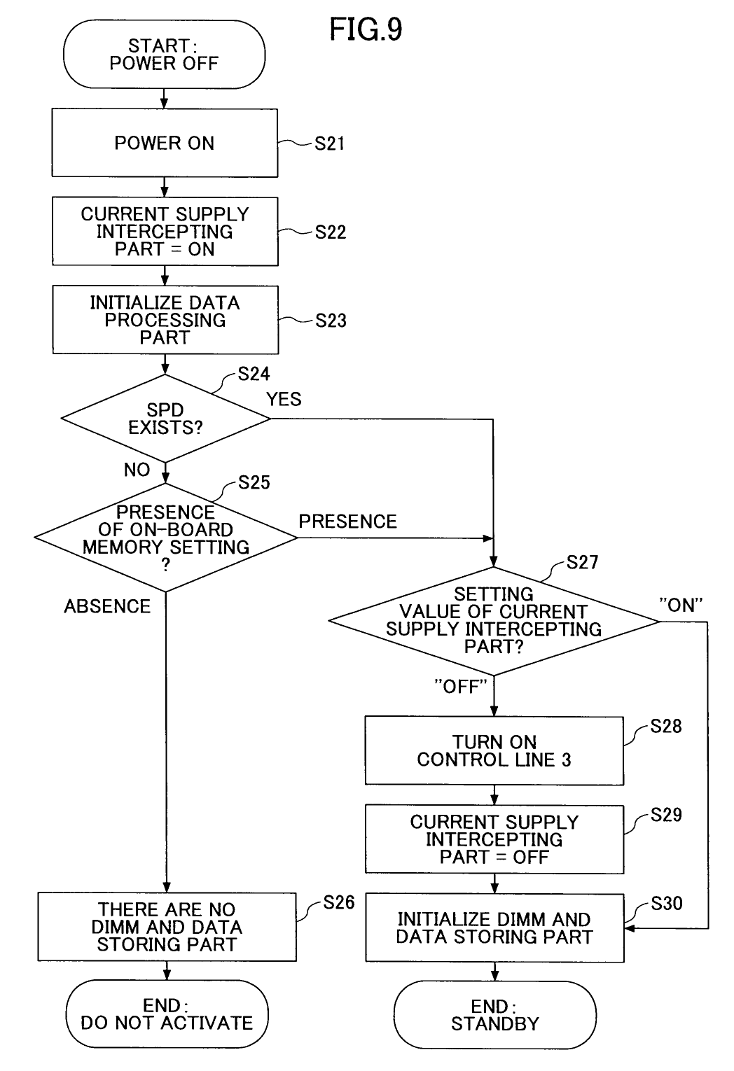

The data processing part 2 supplies or intercepts the current between the terminating resistor 7 and the data signal line 11, in accordance with steps of a flowchart in FIG. 9. FIG. 9 is the flowchart for explaining an example of steps conducted by the electronic device according to the sixth embodiment.

In step S21, an electronic device 1-6 turns on from the power off state. In step S22, the current supply intercepting part 8 is turned on in an initial logic. Also, in step S23, the data processing part 2 is initialized. In step S24, the data processing part 2 determines a presence or an absence of the SPD 4 by whether or not reading the specification of the memory from the SPD 4. When it is determined that the SPD 4 is absence, the data processing part 2 advances to step S25, and determines whether the on-board memory setting is present or absent by checking a presence of an absence of the data storing part 5 of the on-board.

When it is determined that the data storing part 5 of the on-board is absence, the data processing part 2 advances to step S26. In the step S26, the data processing part 2 recognizes that the DIMM 3 and the data storing part 5 of the on-board is connected to the data signal line 11, and stops activating the electronic device 1-6.

On the other hand, when it is determined that the SPD 4 is present in the step S24, or when it is determined that the data storing part 5 of the on-board is present in the step S25, the data processing part 2 determines “ON” (current supply) or “OFF” (interception) of the current supply intercepting part 8 by referring to the control signal table 32, based on the configuration of the DIMM 3 or the data storing part 5 of the on-board connected to the data signal table 32.

When it is determined that “OFF” is set, the data processing part 2 advances to step S28 and turns on the control part 52 (current supply). By turning on the control part 52 (current supply), it is possible for the data processing part 2 to control “ON” (current supply) or “OFF” (interception) of the current supply intercepting part 8.

The data processing part 2 advances to step S29. In the step S29, the data processing part 2 turns off the current supply intercepting part 8 and advances to step S30. On the other hand, when it is determined that “ON” (current supply) is set in the step S27, the data processing part 2 advances to the step S30. In the step S30, after the data processing part 2 initializes the DIMM 3 or the data storing part 5 of the on-board, and the entire electronic device 1-6 is activated and is in the stand-by state.

In the circuit configuration in FIG. 8, when it is determined that it is necessary to control “ON” (current supply) or “OFF” (interception) of the current supply intercepting part 8, by changing a setting from “OFF” (interception) to “ON” (current supply) for the control part 52, it is possible for the data processing part 2 to control the current supply intercepting part 8 to turn on (current supply) or off (interception).

Therefore, the circuit configuration in FIG. 8 prevents a malfunction and the electronic device 1-6 is activated in a fail-safe. It is possible to provide a safer operation to a user.

According to the present invention, it is possible to provide an electronic device which realizes both ensuring the waveform quality and reducing the power consumption.

The present invention is not limited to the specifically disclosed embodiments, and variations and modifications may be made without departing from the scope of the invention.

The present application is based on the Japanese Priority Patent Application No. 2007-057013 filed Mar. 6, 2008, the entire contents of which are hereby incorporated by reference.

What is claimed is:

1. An electronic device having a circuit configuration in which a terminating resistor is connected to a data signal line, said electronic device comprising:
a data processing part;
one or more data storing parts configured to be main storage units of the data processing part;
a termination voltage generating part configured to apply a termination voltage to the data signal line connecting the data processing part to the one or more data storing parts through the terminating resistor; and
a current supply intercepting part configured to be connected between the data signal line and the terminating resistor,
wherein the data processing part detects a configuration of the one or more data storing parts, and enables the terminating resistor to supply current by the current supply intercepting part between the data signal line and the terminating resistor, or disables the terminating resistor to intercept the current between the data signal line and the terminating resistor, based on a detection result.

2. The electronic device as claimed in claim 1, wherein the data processing part detects a connection and a disconnection of the data storing part, and controls the current supply intercepting part based on the detection result.

3. The electronic device as claimed in claim 1, wherein the data processing part detects the configuration of the one or more data storing parts based on a presence or an absence of the one or more data storing parts, and controls the current supply intercepting part based on information indicating a correspondence between the configuration of the one or more data storing parts stored in a non-volatile memory and a current supply or an interception of the current supply intercepting part.

4. The electronic device as claimed in claim 1, further comprising a termination voltage controlling part configured to control the termination voltage generating part to apply the termination voltage when the current is supplied between the data signal line and the terminating resistor, and to stop applying the termination voltage when it is intercepted between the data signal line and the terminating resistor, in synchronizing with the current supply or the interception between the data signal line and the terminating resistor by the current supply intercepting part.

5. The electronic device as claimed in claim 1, wherein the current supply intercepting part is mounted at a position immediately after the data signal line in a path between the data signal line and the terminating resistor.

6. The electronic device as claimed in claim 1, wherein an on-resistor, which is occurred when the current flows to the current supply intercepting part, is used as the current supply intercepting part.

7. The electronic device as claimed in claim 1, further comprising a control part configured to be connected to a control line between the data processing part and the current supply intercepting part, and to supply or intercept the current for the control line between the data processing part and the current supply intercepting part by a control of the data processing part,
wherein the current supply intercepting part enables the terminating resistor by supplying the current between the data signal line and the terminating resistor, and
when disabling the terminating resistor by intercepting the current between the data signal line and the terminating resistor, after supplying the current to the control line between the data processing part and the current supply intercepting part by controlling the control part, the data processing part controls the current supply intercepting part to intercept the current between the data signal line and the terminating resistor, and disables the terminating resistor.
